(19) United States
(12) Patent Application Publication
(10) Pub. No.: US 2014/0182666 A1
(43) Pub. Date: Jul. 3, 2014

(54) QUANTUM DOT-SENSITIZED SOLAR CELL HAVING PBS COUNTER ELECTRODE AND MANUFACTURING METHOD THEREOF

(71) Applicant: Bureau of Energy, Ministry of Economic Affairs, Taipei (TW)

(72) Inventors: Hsisheng Teng, Tainan (TW); Cheng-Yu Lin, Tainan (TW); Tzung-Luen Li, Tainan (TW); Chiao-Yi Teng, Tainan (TW)

(21) Appl. No.: 13/940,873

(22) Filed: Jul. 12, 2013

(30) Foreign Application Priority Data
Dec. 28, 2012 (TW) 101150740

(51) Int. Cl. H01G 9/20; H01L 31/0352

(52) U.S. Cl. CPC H01G 9/2022; H01L 31/035218; H01G 9/2013; Y10S 977/774; Y10S 977/948; B82Y 99/00
USPC 136/254; 136/265; 438/63; 977/774; 977/948

(57) ABSTRACT

Quantum dot-sensitized solar cell and manufacturing method thereof are provided. The proposed quantum dot-sensitized solar cell has a counter electrode with a PbS thin-film layer and a polysulfide electrolyte contacting the PbS thin-film layer.

### CROSS-REFERENCES TO RELATED APPLICATIONS

The application claims the benefits of Taiwan Patent Application Number 101150740, filed on Dec. 28, 2012, in the Taiwan Intellectual Property Office, the disclosures of which are incorporated herein in their entirety by reference.

### FIELD OF THE INVENTION

The present invention relates to a quantum dot-sensitized solar cell (QDSSC) having a PbS counter electrode and a manufacturing method thereof. Specifically, the PbS counter electrode is a photoactive p-type PbS counter electrode.

### BACKGROUND OF THE INVENTION

The dye-sensitized solar cell (DSSC) is a light harvesting component resulting from an optical penetrating layer of TiO2 nano particles coated with a monolayer of dye sensitizer (playing a role in charge-generating). The effective separation and transportation to an external circuit of the opposite charges generated in the good organic dye molecules after the light harvesting gives rise to the high efficiency of the solar cells. The inorganic quantum dots (QDs) are regarded as highly promising next-generation sensitizers because they have a tunable band gap and discrete energy levels for generating multiple excitons through the impact ionization effect.

A further advantage of QDSSCs is that the various QDs' tandem arrangement can be flexibly adjusted to expand the spectral absorption range of the solar cell, and to provide additional light absorption wavelengths so as to enhance the light conversion efficiency via coordinating with a photoactive counter electrode.

To increase the efficiency of charge separation in the sulfide QDSSCs, using the polysulfide electrolyte system is more compatible than using the more common iodide electrolyte in DSSCs. As to the sulfide QDSSCs, there is considerable literature investigating the cell efficiency under various counter electrodes including CoS, CuS, CuS/CoS, Cu₂S, and carbon materials with various structures (nanotube, graphite, carbon black, and mesoporous carbon).

Keeping the drawbacks of the prior arts in mind, and employing experiments and research with persistence and dedication, the applicant has finally conceived a quantum dot-sensitized solar cell having a PbS counter electrode and a manufacturing method thereof

### SUMMARY OF THE INVENTION

It is a primary objective of the present invention to provide a quantum dot-sensitized solar cell having a PbS thin-film, and a polysulfide electrolyte contacting the PbS thin-film. This PbS thin-film is deposited on a fluorine-doped tin oxide by a successive ionic solution coating and reaction process so as to extend the absorption spectrum of the quantum dot-sensitized solar cell to the NIR region. The PbS thin-film layer exhibits the photovoltaic response of a p-type semiconductor when the PbS thin-film layer in the polysulfide electrolyte is illuminated by light, and the PbS thin-film layer shows a quasi-Fermi level shift of 0.25V.

According to the first aspect of the present invention, a quantum dot-sensitized solar cell includes a TiO₂/CuInS₂/CdS/ZnS photoelectrode, a counter electrode having a PbS thin-film layer, and a polysulfide electrolyte disposed between the photoelectrode and the counter electrode.

According to the second aspect of the present invention, a quantum dot-sensitized solar cell includes a counter electrode having a PbS thin-film layer, and a polysulfide electrolyte contacting the PbS thin-film layer.

According to the third aspect of the present invention, a manufacturing method for a quantum dot-sensitized solar cell includes steps of: using a successive ionic solution coating and reaction (SISCR) process to synthesize a PbS thin-film to form a counter electrode having the PbS thin-film; and disposing a polysulfide electrolyte to contact the counter electrode to form the quantum dot-sensitized solar cell.

According to the fourth aspect of the present invention, a manufacturing method for a quantum dot-sensitized solar cell includes a step of: using a successive ionic solution coating and reaction process to synthesize a PbS thin-film on a surface of a fluorine-doped tin oxide (FTO) to form a counter electrode having the PbS thin-film.

The present invention can be best understood through the following descriptions with reference to the accompanying drawings, in which:

### BRIEF DESCRIPTION OF THE DRAWINGS

FIG. 1 shows a schematic diagram of a QDSSC;

FIG. 2 shows a schematic diagram of the energy band and the charge transfer process of the QDSSC shown in FIG. 1; and

FIG. 3 shows Nyquist impedance plots of the PbS electrode with varying SISCR deposition cycles.

### DETAILED DESCRIPTION OF THE PREFERRED EMBODIMENT

Although the following description contains many specifications for the purposes of illustration, anyone of ordinary skill in the art will appreciate that many variations and alterations to the following details are within the scope of the invention. Accordingly, the following preferred embodiment of the invention is set forth without any loss of generality to and without imposing limitations upon, the claimed invention.

A photoactive PbS thin-film layer is deposited on an FTO by an SISCR process so as to extend the absorption spectrum of the quantum dot-sensitized solar cell to the NIR region. The PbS thin-film layer exhibits a photovoltaic response of a p-type semiconductor when the PbS thin-film layer in the polysulfide electrolyte is illuminated by a light, and the PbS thin-film layer shows a quasi-Fermi level shift of 0.25V.

For QDSSCs including a TiO₂/CIS/CdS/ZnS photoanode and a polysulfide electrolyte, the PbS film outperforms Pt and CuS films as a counter electrode even if the CuS film has much higher electrocatalytic activity in polysulfide electrolyte than that of the PbS. The photoactive character of the PbS electrode promotes the photocurrent of the resultant QDSSC, and the p-type conductivity results in a partial tandem junction of the PbS and the anode to enlarge the photovoltage and fill factor. Under one-sun illumination, the QDSSC assembled with the photoactive p-type PbS counter electrode reaches a power conversion efficiency of 4.7%, which is more than 15% greater than that of the cell assembled with the highly electrocatalytic active CuS.

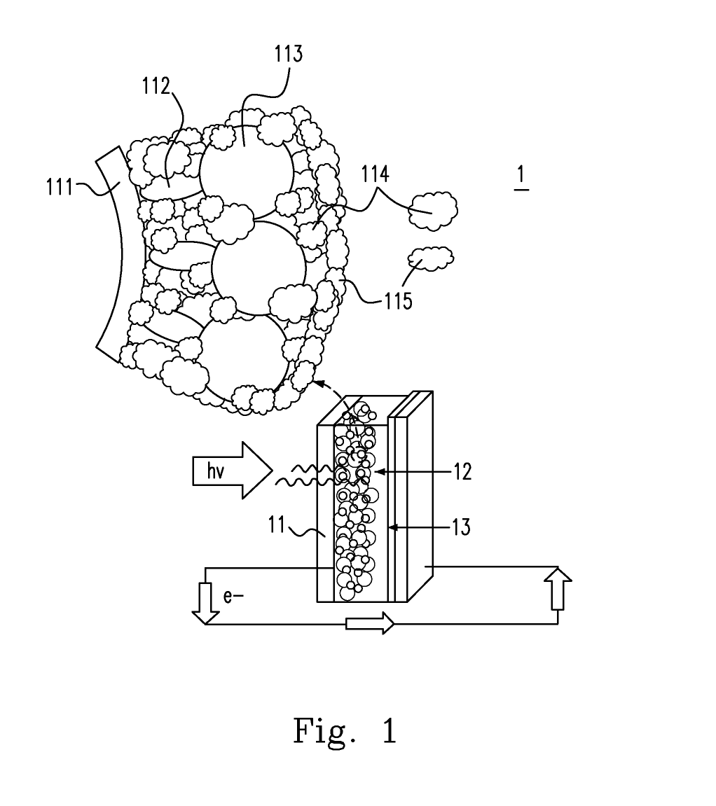

FIG. 1 shows a schematic diagram of a QDSSC. In FIG. 1, the QDSSC includes a TiO₂/CuInS₂/CdS/ZnS photoelectrode 11, a polysulfide electrolyte 12 and a counter electrode 13 (formed by depositing a PbS thin-film layer on an FTO), wherein the arrow hv represents energy (e.g., a sunlight) being incident, and e⁻ represents a transferred charge. Also shown in FIG. 1, the TiO₂/CuInS₂/CdS/ZnS photoelectrode 11 further includes a TiO₂ layer 111, plural CuInS2 particles 113, plural mercaptopropionic acid (MPA) particles 112 used as an interlinker for connecting the TiO₂ layer 111 and the plural CuInS2 particles 113, plural CdS particles 114 and plural ZnS particles 115.

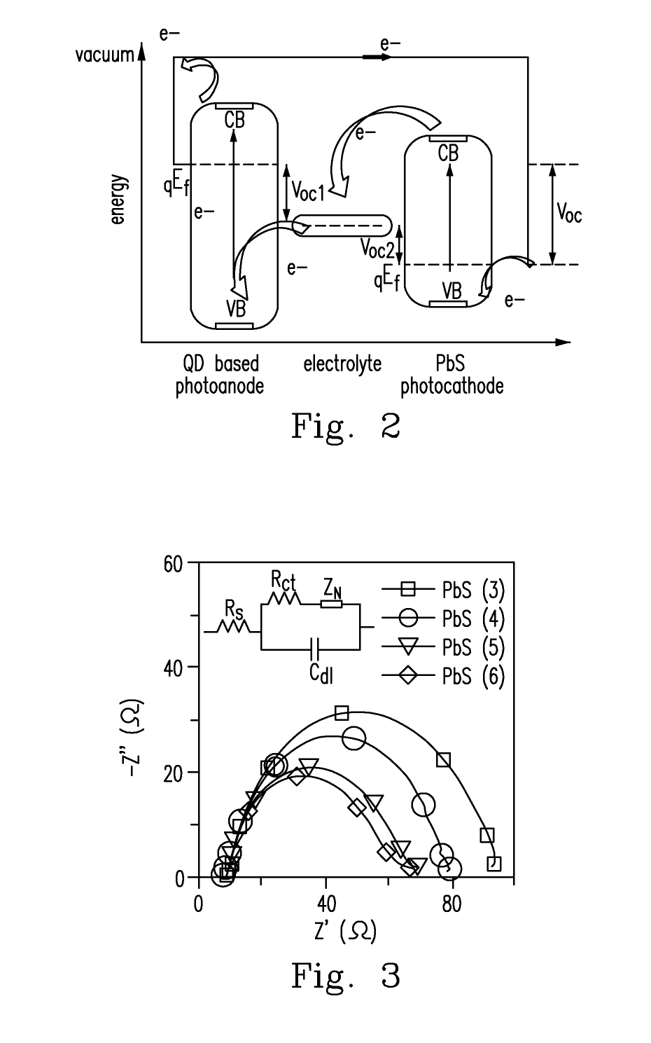

FIG. 2 shows a schematic diagram of the energy band and the charge (e⁻) transfer process of the QDSSC shown in FIG. 1. In FIG. 2, it shows the energy band of the PbS photocathode, the energy band of the electrolyte, and the energy band of the QD based photoanode. As shown in FIG. 2, the PbS electrode is not only a counter electrode, but also a photocathode to facilitate the electron injection to the electrolyte. CB and VB are the conduction band and the valence band of the electrodes, respectively. V_{oc1} stands for the absolute difference between the electrode quasi-Fermi (_{q}E_{f}) level and the electrolyte potential for the photoanode, and V_{oc2} stands for that of the photocathode. The total photovoltage (V_{oc}) in the QDSSC equals to the sum of V_{oc1} and V_{oc2}.

FIG. 3 shows Nyquist impedance plots of the PbS electrode with varying SISCR deposition cycles, where the horizontal axis Z′ indicates the real part resistance of the R_{ct} and the vertical axis −Z″ indicates the imaginary part impedance of the R_{ct}. The number in the parentheses stands for the cycle number of SISCR deposition. The inset at the left top shows the equivalent circuit applied for the impedance data fitting, Rₛ is the ohmic series resistance, C_{d1} is the electric double layer capacitance, R_{ct} is the charge transfer resistance, and Zₙ is the Nernst diffusion impedance. In the low Z′ region at the left-hand side of the Nyquist impedance plots of FIG. 3, the impedance plot with the cycle number of SISCR deposition of 5 has the lower real part resistance of the R_{ct} and the lower imaginary part impedance of the R_{ct}, that is to say, the optimum cycle number of SISCR deposition is 5.

### Embodiments:

1. A quantum dot-sensitized solar cell, comprising:

a TiO₂/CuInS₂/CdS/ZnS photoelectrode;

a counter electrode having a PbS thin-film layer; and

a polysulfide electrolyte disposed between the photoelectrode and the counter electrode.

2. A quantum dot-sensitized solar cell according to Embodiment 1 further comprising an absorption spectrum extended to a near infra-red (NIR) region.

3. A quantum dot-sensitized solar cell according to Embodiment B1 or 2, wherein the photoelectrode further includes a plurality of quantum dots, each of the plurality of quantum dots has a tunable energy gap and a plurality of discrete energy levels, a tandem among the plurality of quantum dots causes a tandem arrangement of an energy gap position of the photoelectrode to be flexibly tunable so as to extend the absorption spectrum to the NIR region.

4. A quantum dot-sensitized solar cell according to anyone of the above-mentioned Embodiments, wherein the counter electrode further includes a fluorine-doped tin oxide (FTO), and the PbS thin-film layer is deposited on the FTO.

5. A quantum dot-sensitized solar cell according to anyone of the above-mentioned Embodiments, wherein the PbS thin-film layer exhibits a photovoltaic response of a p-type semiconductor when the PbS thin-film layer in the polysulfide electrolyte is illuminated by a light, and the PbS thin-film layer shows a quasi-Fermi level shift.

6. A quantum dot-sensitized solar cell according to anyone of the above-mentioned Embodiments, wherein the quasi-Fermi level shift is +0.25V.

7. A quantum dot-sensitized solar cell, wherein the PbS thin-film layer exhibits a property of the p-type semiconductor which causes a partial tandem junction formed between the counter electrode and the photoelectrode such that the quantum dot-sensitized solar cell has a relatively high photovoltage, a relatively high fill factor and a relatively high photovoltaic conversion efficiency.

8. A quantum dot-sensitized solar cell, comprising:

a counter electrode having a PbS thin-film layer; and

a polysulfide electrolyte contacting the PbS thin-film layer.

9. A quantum dot-sensitized solar cell according to Embodiment 8 further comprising a TiO₂/CuInS₂/CdS/ZnS photoelectrode and an absorption spectrum extended to a near infra-red (NIR) region.

10. A quantum dot-sensitized solar cell according to Embodiment 8 or 9, wherein the photoelectrode further includes a plurality of quantum dots, each of the plurality of quantum dots has a tunable energy gap and a plurality of discrete energy levels, a tandem among the plurality of quantum dots causes a tandem arrangement of an energy gap position of the photoelectrode to be flexibly tunable so as to extend the absorption spectrum to the NIR region.

11. A quantum dot-sensitized solar cell according to anyone of the above-mentioned Embodiments, wherein the counter electrode further includes a fluorine-doped tin oxide (FTO), and the PbS thin-film layer is deposited on the FTO.

12. A quantum dot-sensitized solar cell according to anyone of the above-mentioned Embodiments, wherein the PbS thin-film layer exhibits a photovoltaic response of a p-type semiconductor when the PbS thin-film layer in the polysulfide electrolyte is illuminated by a light, and the PbS thin-film layer shows a quasi-Fermi level shift.

13. A quantum dot-sensitized solar cell according to anyone of the above-mentioned Embodiments, wherein the quasi-Fermi level shift is +0.25V.

14. A quantum dot-sensitized solar cell according to anyone of the above-mentioned Embodiments, wherein the PbS thin-film layer exhibits a property of the p-type semiconductor which causes a partial tandem junction formed between the counter electrode and the photoelectrode such that the quantum dot-sensitized solar cell has a relatively high photovoltage, a relatively high fill factor and a relatively high photovoltaic conversion efficiency.

15. A manufacturing method for a quantum dot-sensitized solar cell, comprising steps of:

using a successive ionic solution coating and reaction process to synthesize a PbS thin-film to form a counter electrode having the PbS thin-film; and

disposing a polysulfide electrolyte to contact the counter electrode to form the quantum dot-sensitized solar cell.

16. A manufacturing method according to Embodiment 15 further comprising a step of: providing a TiO₂/CuInS₂/CdS/ZnS photoelectrode, a polysulfide electrolyte and a fluorine-doped tin oxide (FTO) having a surface, wherein the PbS thin-film is synthesized on the surface, the polysulfide electrolyte is disposed between the photoelectrode and the counter electrode, and the using step further comprises steps of:

enclosing an operating area on the surface and dropping a first solution having a lead ion upon the operating area;

scraping the excrescent first solution having the lead ion with a scraper;

dropping a second solution having a sulfide upon the operating area and leveling the second solution having the sulfide with the scraper;

going through a rinse; and

repeating the above-mentioned steps to deposit a nano particle of PbS on the FTO to form the counter electrode having the PbS thin-film.

17. A manufacturing method for a quantum dot-sensitized solar cell, comprising a step of: using a successive ionic solution coating and reaction process to synthesize a PbS thin-film on a surface of a fluorine-doped tin oxide (FTO) to form a counter electrode having the PbS thin-film.

18. A manufacturing method according to Embodiment 17 further comprising steps of:

providing a TiO₂/CuInS₂/CdS/ZnS photoelectrode and a polysulfide electrolyte; and

disposing the polysulfide electrolyte between the photoelectrode and the counter electrode to form the quantum dot-sensitized solar cell.

19. A manufacturing method according to Embodiment 17 or 18, wherein the using step further comprises steps of:

enclosing an operating area on the surface and dropping a first solution having a lead ion upon the operating area;

scraping the excrescent first solution having the lead ion with a scraper;

dropping a second solution having a sulfide upon the operating area and leveling the second solution having the sulfide with the scraper;

going through a rinse; and

repeating the above-mentioned steps to deposit a nano particle of PbS on the FTO to form the counter electrode having the PbS thin-film.

According to the aforementioned descriptions, the present invention provides a quantum dot-sensitized solar cell having a PbS thin-film, and a polysulfide electrolyte contacting the PbS thin-film. This PbS thin-film is deposited on a fluorine-doped tin oxide by a successive ionic solution coating and reaction process so as to extend the absorption spectrum of the quantum dot-sensitized solar cell to the NIR region. The PbS thin-film layer exhibits a photovoltaic response of a p-type semiconductor when the PbS thin-film layer in the polysulfide electrolyte is illuminated by light, and the PbS thin-film layer shows a quasi-Fermi level shift of 0.25V so as to possess the non-obviousness and the novelty.

While the present invention has been described in terms of what are presently considered to be the most practical and preferred embodiments, it is to be understood that the present invention need not be restricted to the disclosed embodiments. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. A quantum dot-sensitized solar cell, comprising:
a TiO₂/CuInS₂/CdS/ZnS photoelectrode;
a counter electrode having a PbS thin-film layer; and
a polysulfide electrolyte disposed between the photoelectrode and the counter electrode.

2. A quantum dot-sensitized solar cell according to claim 1 further comprising an absorption spectrum extended to a near infra-red (NIR) region.

3. A quantum dot-sensitized solar cell according to claim 2, wherein the photoelectrode further includes a plurality of quantum dots, each of the plurality of quantum dots has a tunable energy gap and a plurality of discrete energy levels, a tandem among the plurality of quantum dots causes a tandem arrangement of an energy gap position of the photoelectrode to be flexibly tunable so as to extend the absorption spectrum to the NIR region.

4. A quantum dot-sensitized solar cell according to claim 1, wherein the counter electrode further includes a fluorine-doped tin oxide (FTO), and the PbS thin-film layer is deposited on the FTO.

5. A quantum dot-sensitized solar cell according to claim 1, wherein the PbS thin-film layer exhibits a photovoltaic response of a p-type semiconductor when the PbS thin-film layer in the polysulfide electrolyte is illuminated by a light, and the PbS thin-film layer shows a quasi-Fermi level shift.

6. A quantum dot-sensitized solar cell according to claim 5, wherein the quasi-Fermi level shift is +0.25V.

7. A quantum dot-sensitized solar cell according to claim 5, wherein the PbS thin-film layer exhibits a property of the p-type semiconductor which causes a partial tandem junction formed between the counter electrode and the photoelectrode such that the quantum dot-sensitized solar cell has a relatively high photovoltage, a relatively high fill factor and a relatively high photovoltaic conversion efficiency.

8. A quantum dot-sensitized solar cell, comprising:
a counter electrode having a PbS thin-film layer; and
a polysulfide electrolyte contacting the PbS thin-film layer.

9. A quantum dot-sensitized solar cell according to claim 8 further comprising a TiO₂/CuInS₂/CdS/ZnS photoelectrode and an absorption spectrum extended to a near infra-red (NIR) region.

10. A quantum dot-sensitized solar cell according to claim 9, wherein the photoelectrode further includes a plurality of quantum dots, each of the plurality of quantum dots has a tunable energy gap and a plurality of discrete energy levels, a tandem among the plurality of quantum dots causes a tandem arrangement of an energy gap position of the photoelectrode to be flexibly tunable so as to extend the absorption spectrum to the NIR region.

11. A quantum dot-sensitized solar cell according to claim 8, wherein the counter electrode further includes a fluorine-doped tin oxide (FTO), and the PbS thin-film layer is deposited on the FTO.

12. A quantum dot-sensitized solar cell according to claim 8, wherein the PbS thin-film layer exhibits a photovoltaic response of a p-type semiconductor when the PbS thin-film layer in the polysulfide electrolyte is illuminated by a light, and the PbS thin-film layer shows a quasi-Fermi level shift.

13. A quantum dot-sensitized solar cell according to claim 12, wherein the quasi-Fermi level shift is +0.25V.

14. A quantum dot-sensitized solar cell according to claim 12, wherein the PbS thin-film layer exhibits a property of the p-type semiconductor which causes a partial tandem junction formed between the counter electrode and the photoelectrode such that the quantum dot-sensitized solar cell has a relatively high photovoltage, a relatively high fill factor and a relatively high photovoltaic conversion efficiency.

15. A manufacturing method for a quantum dot-sensitized solar cell, comprising steps of:
using a successive ionic solution coating and reaction process to synthesize a PbS thin-film to form a counter electrode having the PbS thin-film; and
disposing a polysulfide electrolyte to contact the counter electrode to form the quantum dot-sensitized solar cell.

16. A manufacturing method according to claim 15 further comprising a step of: providing a TiO₂/CuInS₂/CdS/ZnS photoelectrode, a polysulfide electrolyte and a fluorine-doped tin oxide (FTO) having a surface, wherein the PbS thin-film is synthesized on the surface, the polysulfide electrolyte is disposed between the photoelectrode and the counter electrode, and the using step further comprises steps of:
enclosing an operating area on the surface and dropping a first solution having a lead ion upon the operating area;
scraping the excrescent first solution having the lead ion with a scraper;
dropping a second solution having a sulfide upon the operating area and leveling the second solution having the sulfide with the scraper;
going through a rinse; and
repeating the above-mentioned steps to deposit a nano particle of PbS on the FTO to form the counter electrode having the PbS thin-film.

17. A manufacturing method for a quantum dot-sensitized solar cell, comprising a step of: using a successive ionic solution coating and reaction process to synthesize a PbS thin-film on a surface of a fluorine-doped tin oxide (FTO) to form a counter electrode having the PbS thin-film.

18. A manufacturing method according to claim 17 further comprising steps of:
providing a TiO₂/CuInS₂/CdS/ZnS photoelectrode and a polysulfide electrolyte; and
disposing the polysulfide electrolyte between the photoelectrode and the counter electrode to form the quantum dot-sensitized solar cell.

19. A manufacturing method according to claim 17, wherein the using step further comprises steps of:
enclosing an operating area on the surface and dropping a first solution having a lead ion upon the operating area;
scraping the excrescent first solution having the lead ion with a scraper;
dropping a second solution having a sulfide upon the operating area and leveling the second solution having the sulfide with the scraper;
going through a rinse; and
repeating the above-mentioned steps to deposit a nano particle of PbS on the FTO to form the counter electrode having the PbS thin-film.
